(19) United States
(12) Patent Application Publication
(10) Pub. No.: US 2012/0110400 A1
(43) Pub. Date: May 3, 2012

(54) Method and Apparatus for Performing Memory Interface Calibration

(75) Inventors: Valavan Manohararajah, Scarborough (CA); Ivan Bluno, Woodbridge (CA); Przemek Guzy, Markham (CA); Kalen B. Brunham, Toronto (CA)

(73) Assignee: Altera Corporation, San Jose, CA (US)

(21) Appl. No.: 12/959,666

(22) Filed: Dec. 3, 2010

Related U.S. Application Data
(60) Provisional application No. 61/409,113, filed on Nov. 1, 2010.
(60) Provisional application No. 61/456,186, filed on Nov. 2, 2010.

(51) Int. Cl. G11C 29/00; G11C 7/00; G06F 11/16

(52) U.S. Cl. 714/719; 365/193; 714/E11.054

(57) ABSTRACT

A universal memory interface on an integrated circuit includes an external memory interface unit operable to perform data rate conversion for a data signal between a first rate associated with the integrated circuit and a second rate associated with a memory system. The universal memory interface also includes a sequencer unit operable to calibrate at least one of a delay for the data signal and a delay for a strobe for the data signal by executing a calibration procedure instruction.

### RELATED APPLICATION

This application claims priority to provisional U.S. patent application Ser. No. 61/409,113 filed Nov. 1, 2010, entitled “Method and Apparatus for Performing Memory Interface Calibration”, and U.S. patent application Ser. No. 61/456,186 filed Nov. 2, 2010, entitled “Method and Apparatus for Performing Memory Interface Calibration”, the full and complete subject matter of which is hereby expressly incorporated by reference in its entirety.

### FIELD

Embodiments of the present invention relate to hardware for supporting source synchronous memory standards. More specifically, embodiments of the present invention relate to a method and apparatus for performing memory interface calibration on integrated circuits such as field programmable gate arrays (FPGAs).

### BACKGROUND

Source synchronous memory standards are used to enable high-speed data transfer between processing devices and memory systems. Some of these standards include reduced latency dynamic random access memory (RLDRAM), quad data rate (QDR), and double data rate (DDR).

Memory interfaces for memory systems compliant with source synchronous memory standards perform double data rate transfers where data is transferred on both the rising and falling edges of the clock. When there is no setup or hold time requirement for the data, a data valid window of a half cycle is available. However, when setup and hold time requirements are present, the data valid window can be much smaller. The presence of board layout, process, voltage, and temperature variations further reduces the size of the data valid window. Consequently, the slightest amount of skew on the data lines could likely result in incorrect data transfers.

A memory interface implemented on integrated circuits such as FPGAs are operable to perform low level data rate conversions and synchronization of clocks to allow components on the integrated circuits to communicate with memory system. When designing an external memory interface, designers encounter the challenge of providing a design that supports multiple source synchronous memory standards without requiring a large number of changes. This challenge extends to designing memory interfaces capable of performing calibration necessary for operating with a specific source synchronous memory standard.

### SUMMARY

According to an embodiment of the present invention, a universal memory interface includes a sequencer unit operable to calibrate at least one of a data delay and a strobe delay between the universal memory interface and a memory system. The calibration results in center aligning a data signal with a clock that strobes it and expands a valid window for sampling the data. The sequencer unit may implement a processor or a finite state machine to execute a calibration procedure. The sequencer includes additional components to implement lower level primitives associated with adjusting delay chains and implementing low-level read and write commands to the memory system. According to an aspect of the present invention where a processor is implemented to execute the calibration procedure, the calibration procedure is implemented using program code and the calibration procedure may be loaded onto the integrated circuit in response to identifying a type of the memory system.

### BRIEF DESCRIPTION OF THE DRAWINGS

The features and advantages of embodiments of the present invention are illustrated by way of example and are not intended to limit the scope of the embodiments of the present invention to the particular embodiments shown.

FIG. 1 illustrates a universal memory interface and a memory controller implemented on an integrated circuit according to an exemplary embodiment of the present invention.

FIG. 2 illustrates a double data rate memory protocol implemented by an external interface unit according to an exemplary embodiment of the present invention.

FIGS. 3A and 3B illustrate examples of data transmitted to the memory system according to an embodiment of the present invention.

FIG. 4 illustrates a sequencer unit according to an embodiment of the present invention.

FIGS. 5A and 5B illustrate pattern registers implemented by a read write manager according to an embodiment of the present invention.

FIG. 6 is a flow chart illustrating a calibration procedure according to an embodiment of the present invention.

FIGS. 7A and 7B illustrate an example where DQ delays are swept according to an embodiment of the present invention.

FIG. 8 is a flow chart illustrating a method for designing and building a system with a universal memory interface on a target device according to an embodiment of the present invention.

FIG. 9 illustrates an integrated circuit which a universal memory interface may be implemented on according to an embodiment of the present invention.

### DETAILED DESCRIPTION

In the following description, for purposes of explanation, specific nomenclature is set forth to provide a thorough understanding of embodiments of the present invention. It will be apparent to one skilled in the art that specific details in the description may not be required to practice the embodiments of the present invention. In other instances, well-known circuits, devices, and components are shown in block diagram form to avoid obscuring embodiments of the present invention unnecessarily.

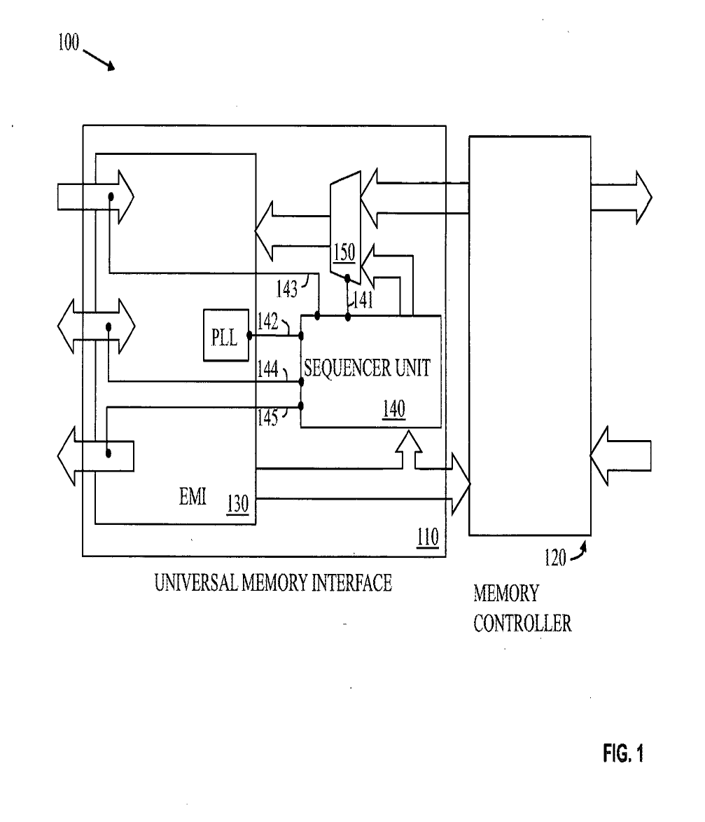

FIG. 1 illustrates a portion of an integrated circuit 100 that includes a universal memory interface 110 and a memory controller 120 according to an exemplary embodiment of the present invention. The integrated circuit 100 may be coupled to a high-speed memory system to its left (not shown) that operates at a data rate higher than that of the integrated circuit 100. The memory controller 120 on the integrated circuit 100 receives instructions directed to the memory system. The memory controller 120 interprets the instructions and schedules the instructions for execution. The memory controller 120 also converts the instructions to lower level memory commands and transmits the commands to the universal memory interface 110. The commands may, for example, coordinate aspects of bank, row, and column management, and memory refresh of the memory system.

The universal memory interface 110 includes an external memory interface (EMI) 130, which handles low level data rate conversions and timing specifics of communicating with the memory system. According to an embodiment of the present invention, the external memory interface 130 provides a layer that converts a high speed double data rate interface provided by modern high-speed memory devices such as RLDRAM, QDR, and DDR into a single or half-rate interface suitable for use within the integrated circuit 100.

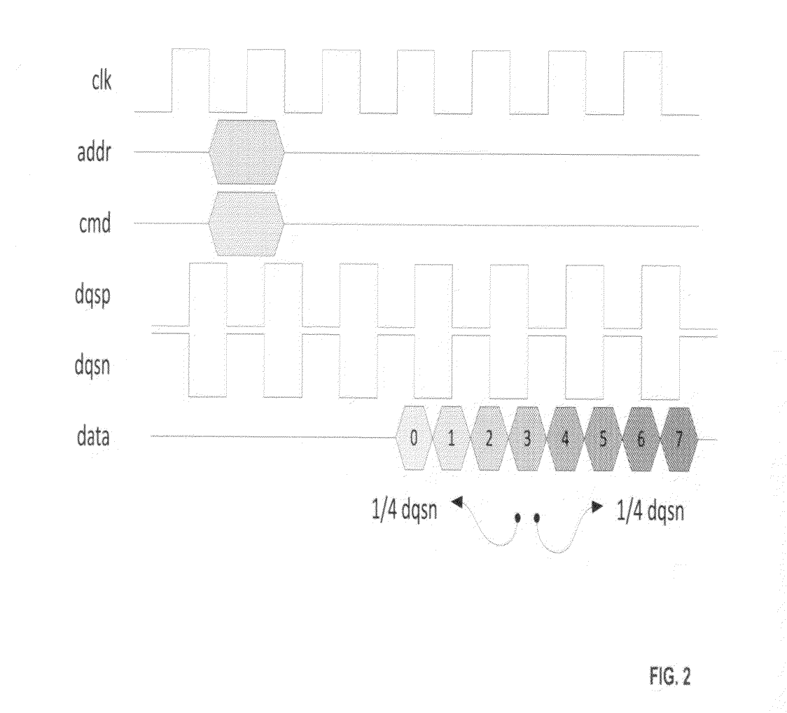

FIG. 2 illustrates a double data rate memory protocol implemented by an external interface unit according to an exemplary embodiment of the present invention. Address and command signals are sampled by clock signal clk while data is sampled on the positive edge of clock signals dqsp and dqsn. Clock signals dqsp and dqsn are differential clocks which facilitate double rate data. Although the data, dqsp, and dqsn are shown as being center aligned, slight variations in delay may lead to violations in setup or hold time at the memory system.

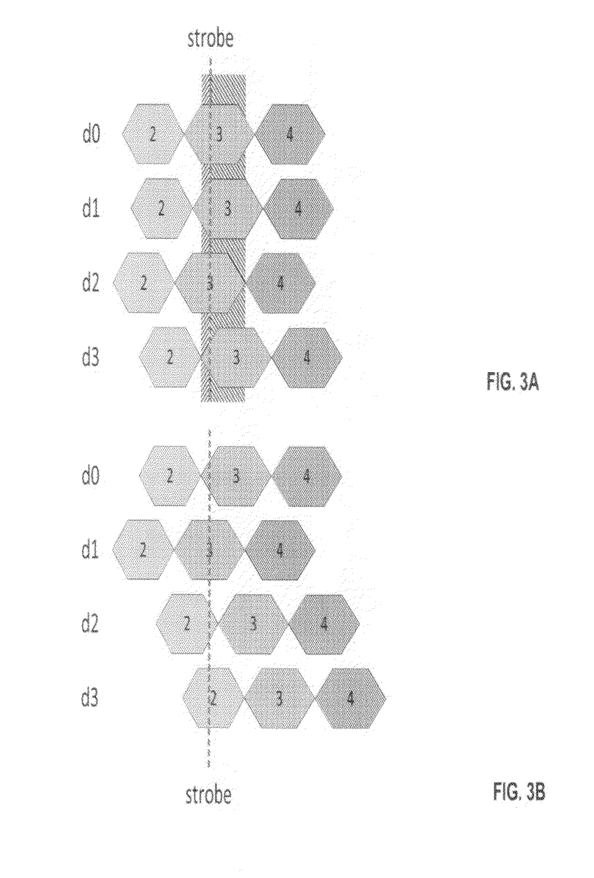

FIGS. 3A illustrates a first example of data transmitted to a memory system from an integrated circuit according to an embodiment of the present invention. In this example, an external memory interface supports four data bits, d0-d3. As illustrated, skew is present on the data pins of the memory system that may result in misalignment at their destination. The skew on the data signals results in different setup and hold margins for each of the data signals.

FIG. 3B illustrates a second example of data transmitted to the memory system from the integrated according to an embodiment of the present invention. In this example, skew has resulted in the misalignment of data bits d2 and d3 which would result in the wrong data being sampled at a destination.

Referring back to FIG. 1, the sequencer unit 140 enables high frequency memory interface operation by centering the data and data clocks in the presence of delay variation. According to an embodiment of the sequencer unit 140, a calibration procedure is performed that determines appropriate delay settings that would align the various data signals. According to an embodiment of the present invention, the calibration procedure performs a series of reads and writes on test data in the memory system while varying delays on the data and strobe signals to determine a data valid window. The calibration procedure identifies adjustments to be made to data and strobe delays in order to expand or maximize the data valid window for each data signal. The sequencer unit 140 may perform this calibration procedure during startup or initialization of the integrated circuit 100 and/or the memory system. The sequencer unit 140 may also perform the calibration procedure after startup or initialization during runtime in response to periodic requests by the memory controller 120 or another agent external to the universal memory interface 110. This allows the sequencer unit 140 to account for variations associated with voltage and temperature that might not have been present during the initial calibration.

The sequencer unit 140 uses connections 141-145 to transmit control signals to communicate with external memory interface 130 and selector 150. A control signal may be transmitted on connection 141 to program selector 150. Selector 150 is operable to control whether the memory controller 120 or the sequencer 140 has a direct connection to the external memory interface 130. During calibration, selector 150 provides the sequencer unit 140 with a direct connection to the external memory interface 130. During normal operation of the universal memory interface 100, the selector 150 provides the memory controller 120 with a direct connection to the external memory interface 130. A control signal may be transmitted on connection 142 to direct a phase locked loop in the external memory interface 130 to adjust a phase of a clock signal during calibration. Control signals transmitted on connections 143-145 may be used to change input and output delays by controlling delay chains associated with data (DQ), data mask (DM), and data strobe (DQS) signals. Control signals transmitted on connections 143-145 may also be used to set various latencies within the external memory controller 130 and to provide the external memory controller 130 with information as to when the memory initialization protocol has stopped running.

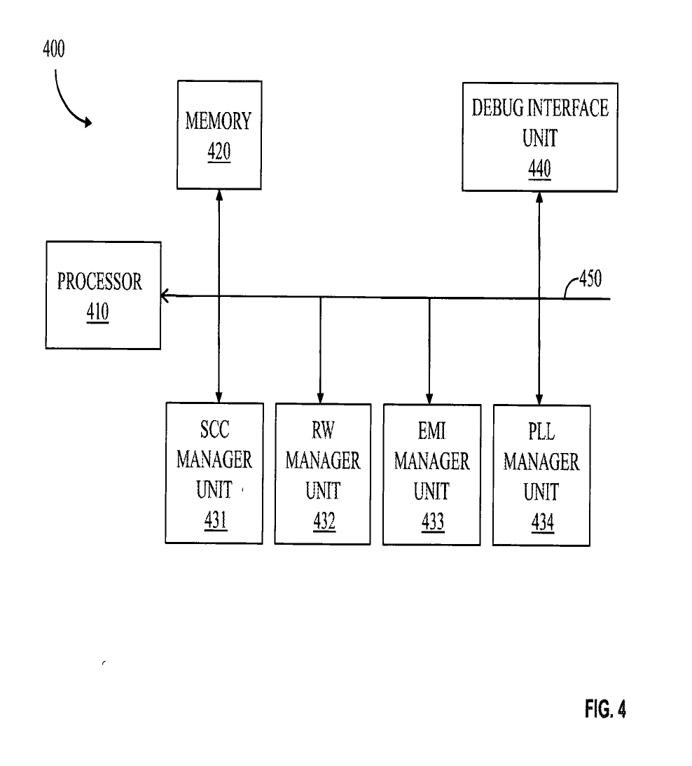

FIG. 4 illustrates a sequencer unit 400 according to an embodiment of the present invention. The sequencer unit 400 may be used to implement the sequencer unit 140 illustrated in FIG. 1. The sequencer unit 400 includes a processor 410 and memory 420. According to an embodiment of the present invention, the calibration procedure is written in software code, stored in the memory 420, and executed by the processor 410. By having the processor 410 control execution of the calibration procedure, modifications to the calibration procedure may be made by updating the software code stored in memory 420.

The sequencer unit 400 includes a plurality of managers 431-434 that implement timing, device, and memory protocol specific tasks. By equipping managers with the functionalities to handle lower level timing, memory protocol, and bit manipulation operations, the calibration procedure executed by the processor 410 may be focused on higher level functionalities specific to the memory system type. According to an embodiment of the present invention where the integrated circuit is a FPGA, the managers 431-434 are hardware components with functionalities specified in register transfer level (RTL) code and implemented by logic on the FPGA. The processor 410, memory 420, managers 431-434, and debug interface 440 are connected via a bus 450. It should be appreciated that the bus 450 may be implemented by a single bus or a plurality of buses and allow the components in the sequencer unit 400 to transmit data to one another.

The sequencer unit 400 includes a debug interface unit 440. The debug interface unit 440 is operable to provide a mechanism for interacting with the managers 431-434 and for tracking the progress of the calibration procedure. For example, the debug interface unit 440 may provide a user interface to examine data valid windows, data/strobe delay chain settings, and specified calibration stages. The debug interface 440 may be used as a debugging tool for the managers 431-434, the calibration procedure in memory 420, and the external memory interface. According to an embodiment of the present invention, the debug interface unit 440 provides an interface for a calibration procedure to be loaded into memory 420. The calibration procedure may be loaded into memory 420 in response to identifying a type of memory system that is connected to the integrated circuit. Alternatively, the calibration procedure may be loaded into memory 420 in response to there being a new or modified calibration procedure.

The scan chain (SCC) manager unit 431 is operable to set various delays and/or phase adjustments on the input outputs and strobes used to latch data on the integrated circuit which the universal memory interface resides on. The setting may be performed in response to the calibration procedure. According to an embodiment of the present invention, dynamic delay chains are present on the input, output, and output enable paths of the universal memory interface which are configurable at runtime. The scan chain manager unit 431 may accesses these chains to add delay on incoming and outgoing signals.

The read write (RW) manager unit 432 is operable to issue protocol specific low-level read and write commands to the memory system during calibration in response to the calibration procedure. The types of commands that are supported include write configuration, refresh, write guarantee, write/read burst, and write/read back-to-back.

According to an embodiment of the sequencer unit 400, the read write manager 432 includes a finite state machine, a global timer, and independent data paths for address/command, write data, and read data. In response to receiving a request to access the memory system, the finite state machine transmits an appropriate command to the memory system via the appropriate data path. The global timer is also set to run to inform the finite state machine of an appropriate period of time to transmit the command as required by the memory system. In one embodiment, the data paths are activated by the finite state machine during a period of time specified in operation code received by the calibration procedure.

According to an embodiment of the read write manager unit 432, a pattern register is implemented when writing to and reading from a memory system. When writing data to the memory system, write data may be constructed from a pattern register that specifies how data lines vary over a write burst. An inversion bit in the pattern register controls how data changes across bit lanes. Use of the pattern register allows the sequencer unit 400 to conserve use of memory 420.

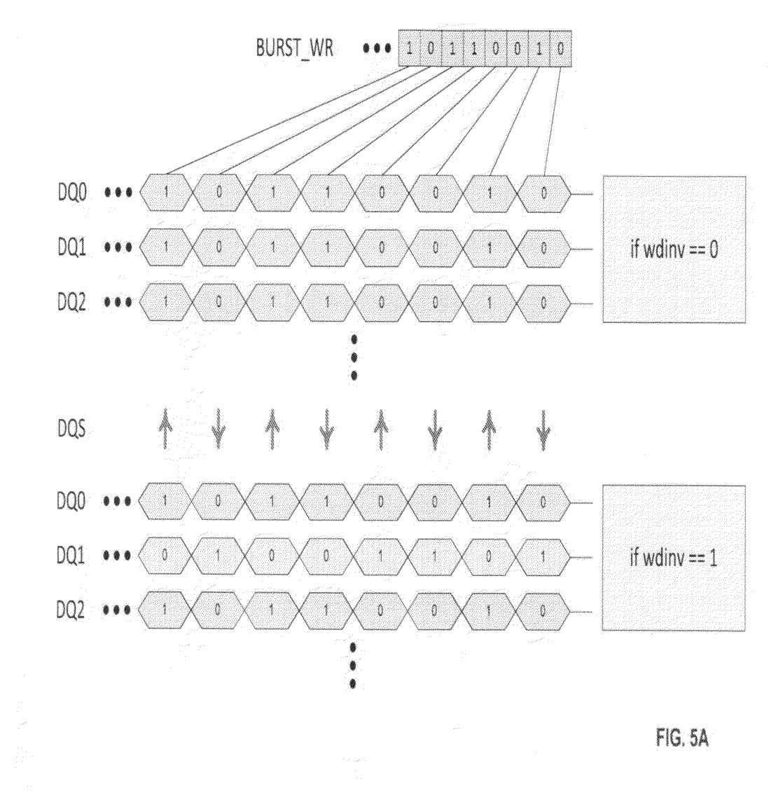

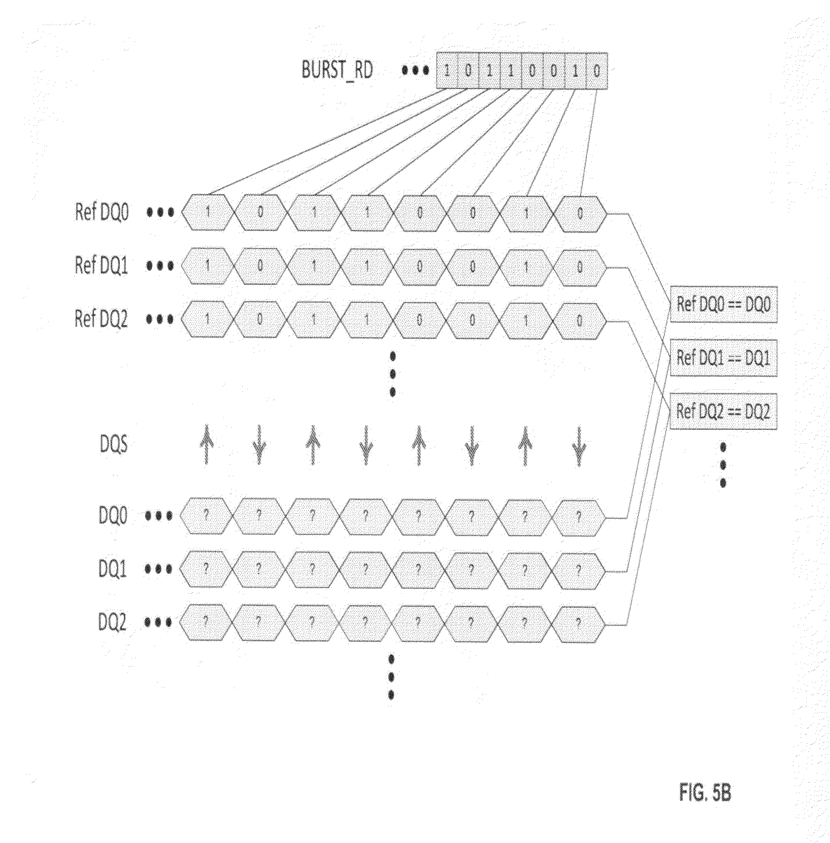

FIG. 5A illustrates an example embodiment of using a pattern register for a write burst. The inversion bit in the pattern register controls how the reference pattern changes across bit lanes. Referring back to FIG. 4, use of the pattern register for reading data frees the processor 410 from having to check the correctness of incoming data and eliminates need for a barrel shifter in the processor 410. Memory 420 is also conserved from not having to store incoming burst. FIG. 5B illustrates an example embodiment of using a pattern register for a read burst. When reading data from the memory system, read data may be compared against a reference pattern in the pattern register.

Referring back to FIG. 4, the external memory interface (EMI) manager unit 433 is operable to provide an interface to transmit commands to the external memory interface. The external memory interface manager unit 433 is also operable to adjust settings of first in first out (FIFOs) inside the external memory interface during calibration. According to an embodiment of the present invention, a first FIFO, “VFIFO”, is used to determine when data from the memory system is ready to be sampled. A second FIFO, “LFIFO”, synchronizes data by storing the data sampled from memory until it is ready to be presented to a user. The external interface manager unit 433 adjusts settings on the VFIFO and LFIFO in order to reduce latency. The external memory interface manager unit 433 also provides a signal to the external memory interface to indicate when a memory system initialization sequence is completed.

The PLL manager unit 434 is operable to provide access to the external memory interface's phase locked loop. PLLs are used to generate a number of clocks used by the external memory interface and memory controller. The PLL manager unit 434 provides an interface to change the phases of the clocks during calibration.

Functions of the sequencer unit 400 such as delay chain management, memory system management, external memory face interface, and PLL management, and calibration procedure execution are assigned to components on the sequencer unit 400 in a modular fashion to allow for efficient design and implementation. Utilization of a processor 410 and memory 420 to control execution of the calibration instead of a finite state machine requires less space on an integrated circuit. By using the processor 410 and memory 420 to control execution of the calibration procedure, the calibration procedure may also be debugged, expanded, or modified without having to change other components in the sequencer unit 400. Thus, recompilation of a design for components implementing the sequencer unit 400 is not required when the calibration procedure is changed.

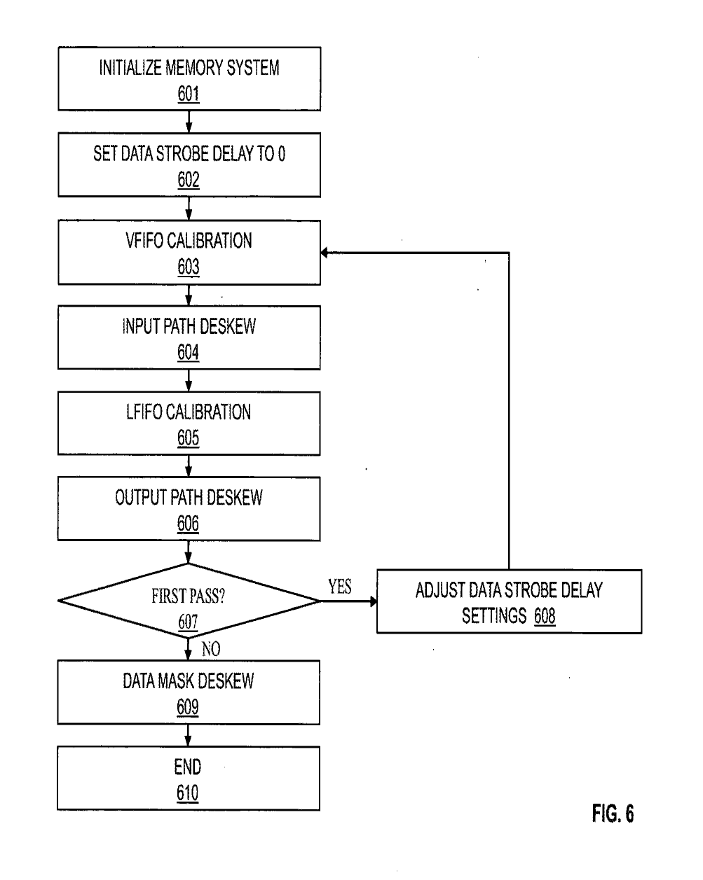

FIG. 6 is a flow chart illustrating a calibration procedure according to an embodiment of the present invention. The calibration procedure described may be executed by a processor on a sequencer unit according to an embodiment of the present invention. According to an embodiment of the present invention, calibration involves configuring an external memory interface and input outputs of the external memory interface to reliability transfer data to and from the memory system. One aspect of calibration involves adjusting settings applied to FIFOs within the external memory interface to reduce latency and to ensure that read valid signals are generated at the appropriate time. A second aspect of calibration involves adjusting settings applied to input output delay chains and PLLs so that data transfers to and from memory are centered with respect to the data clock.

At 601, a memory system is initialized. Memory system initialization may involve asserting a reset signal, stopping a clock, loading registers in the memory system, and/or other procedures required for the memory system to be initialized. Memory system initialization configures the memory system to support requested burst lengths, read and write latencies, and other user requested memory parameters. According to an embodiment of the present invention, the calibration procedure prompts a read write manager and external memory interface manager unit on a sequencer unit to issue appropriate instructions to perform initialization.

At 602, the data strobe delay is set to zero. According to an embodiment of the present invention, the calibration procedure prompts the scan chain manager unit to set the data strobe delay to zero.

At 603, VFIFO calibration is performed. According to an embodiment of the present invention, VFIFO calibration involves identifying a cycle in which data is returned from the memory system. According to an embodiment of the present invention, the calibration procedure prompts the external memory interface manager unit to calibrate the VFIFO.

At 604, input path deskew is performed. According to an embodiment of the present invention, input path deskew involves determining a delay that is to be applied on the input path of a data signal so that the input data and input data clock (strobe) are aligned. A plurality of delay settings may be tested to identify reads that can be successfully be completed. According to one exemplary embodiment, delay settings that result in successful reads of the input data may be saved and the midpoint of the range of settings may be applied to the input data path at the end of the calibration procedure. According to an embodiment of the present invention, the calibration procedure prompts the scan chain manager unit to adjust delay settings while the read write manager unit issues instructions to write and read test data.

At 605, LIFO calibration is performed. According to an embodiment of the present invention, LIFO calibration involves lowering the read latency until the reduce latency that may be the minimum latency is still able to guarantee reliable reads. According to an embodiment of the present invention, the calibration procedure prompts the external memory interface manager unit to calibrate the LIFO. The external memory interface manager unit may increase or decrease a latency value identified by the calibration procedure.

At 606, output path deskew is performed. According to an embodiment of the present invention, output path deskew involves determining a delay that is to be applied to the output path of a data signal so that the output data and output data clock (strobe) are aligned. A plurality of delay settings may be tested to identify writes that can be successfully be completed. According to one exemplary embodiment, delay settings that result in successful writes of the output data may be saved and the midpoint of the range of settings may be applied to the output data path at the end of the calibration procedure. According to an embodiment of the present invention, the calibration procedure prompts the scan chain manager unit to adjust delay settings while the read write manager unit issues instructions to write and read test data.

At 607, it is determined whether the current pass through the calibration procedure is a first pass through the calibration procedure. If the current pass is the first pass, control proceeds to 608. If the current pass is not the first pass, control proceeds to 609.

At 608, the data strobe delay is adjusted to a non-zero value. According to an embodiment of the present invention, the non-zero value selected for adjustment may be based on the range of delay settings that resulted in successful reads of input data and writes of output data in order to maximize the use of the delay setting for a next pass of input path deskew and output path deskew. According to an embodiment of the present invention, the calibration procedure prompts the scan chain manager unit to set the data strobe delay to a value determined by the calibration procedure. Control returns to 603.

At 609, data mask deskew is performed. According to an embodiment of the present invention, data mask deskew involves determining a delay that is to be applied to a data mask signal so that the data mask signal and data mask clock (strobe) are aligned. Similar to the input path deskew and output path deskew procedures, according to one embodiment, a plurality of delay values for a data mask pin may be swept and the midpoint of the range of successful reads and writes may be applied at the end. According to an embodiment of the present invention, the calibration procedure prompts the scan chain manager unit to adjust delay settings while the read write manager unit issues instructions to write and read test data. According to an embodiment of the present invention, write and reads are tested separately when performing data mask deskew.

At 610, control terminates the procedure.

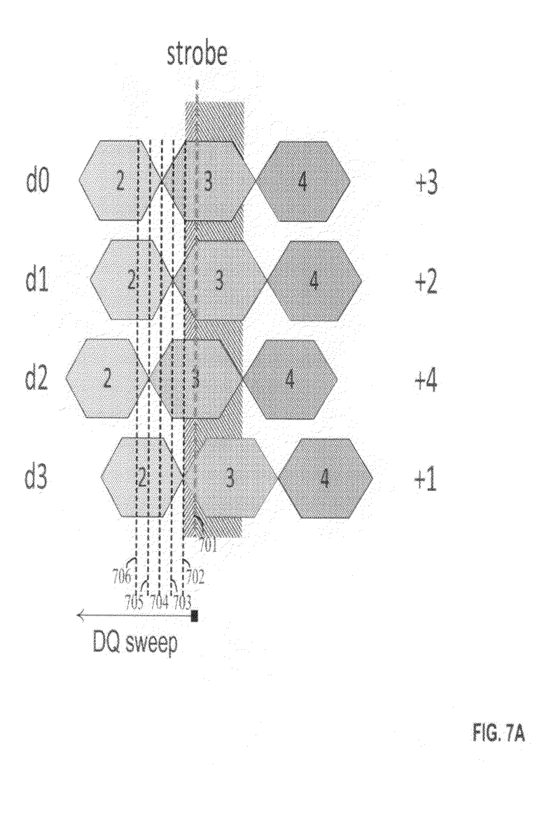

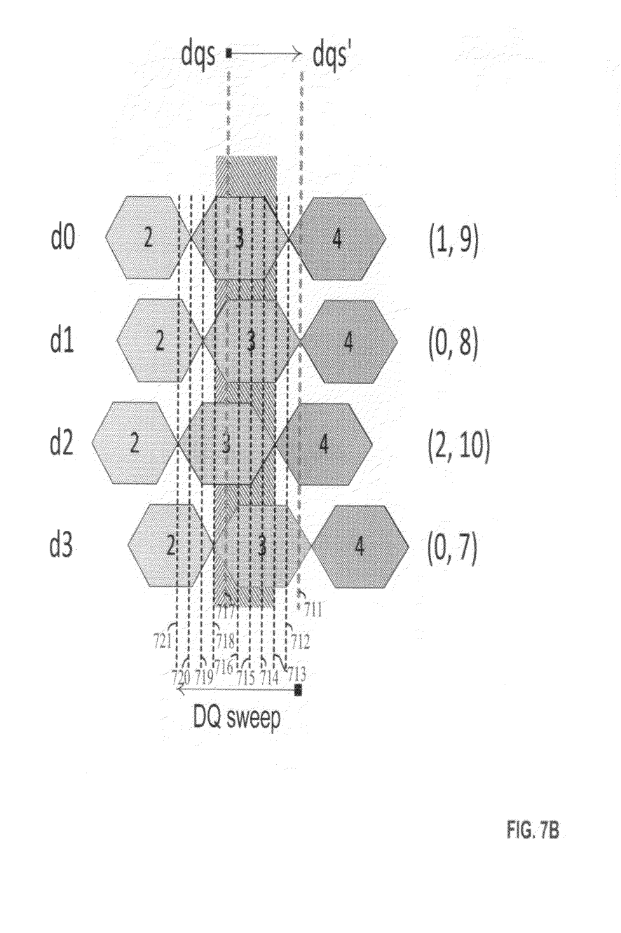

FIGS. 7A and 7B illustrate an example of performing multi-pass path deskew according to an embodiment of the present invention. FIGS. 7A and 7B illustrate data transmitted to a memory system from an integrated circuit according to an embodiment of the present invention. In this example, an external memory interface supports four data bits, d0-d3. In FIG. 7A, the strobe delay is set to zero by setting a DQS pin to zero. The delays on the DQ pins, d0-d3, are “swept” by applying a plurality of delays before performing a read/write. As illustrated, the delay settings from 0 to 3 (701-703) result in successful read/writes for d0. Delay settings from 0 to 2 (701-702) result in successful read/writes for d1. Delay settings from 0 to 4 (701-704) result in successful read/writes for d2. Delay settings from 0 to 1 (701-702) result in successful read/writes for d3. With the strobe delay set to zero, it is unclear what would happen below zero. Based on the observations in FIG. 7A, strobe delay is set to six in FIG. 7B.

FIG. 7B illustrates sweeping DQ delays with an adjusted strobe delay according to an embodiment of the present invention. When sweeping the DQ delays with the adjusted strobe delay, a wider data valid window is observed. Delay settings from 1 to 9 (712-720) result in successful read/writes for d0. Delay settings from 0 to 8 (711-718) result in successful read/writes for d1. Delay settings from 2 to 10 (713-721) result in successful read/writes for d2. Delay settings from 0 to 7 (711-717) result in successful read/writes for d3. When selecting a delay setting that centers the data pin with respect to the strobe, improvements to setup and hold margins are achieved. In the example illustrated in FIGS. 7A and 7B, procedures 602, 604/606, 607, and 608 from FIG. 6 are performed in part.

According to an alternate embodiment of the sequencer unit illustrated in FIG. 4, control of the calibration procedure is executed by a finite state machine instead of processor 410. In this embodiment, managers 431-434 implement timing, device, and memory protocol specific tasks. By equipping managers with the functionalities to handle lower level timing, memory protocol, and bit manipulation operations, the calibration procedure executed by the finite state machine may be focused on higher level functionalities specific to the memory system type. The finite state machine may implement the calibration procedure described with reference to FIGS. 6 and 7A and 7B.

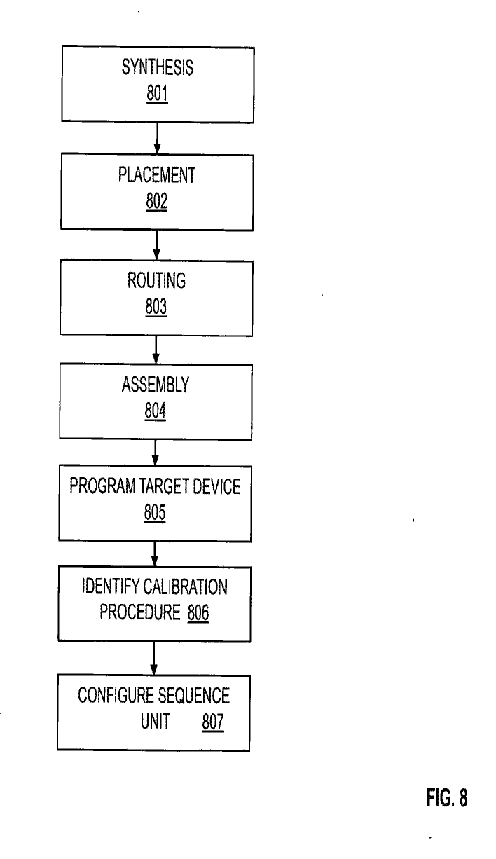

FIG. 8 is a flow chart illustrating a method for designing and building a system with a universal memory interface on a target device according to an embodiment of the present invention. The target device may be an FPGA, application specific integrated circuit (ASIC), a structured ASIC, or other programmable device. According to one embodiment, the procedure illustrated in FIG. 1 may be performed by a computer aided design (CAD)/electronic design automation (EDA) tool implemented on a computer system. At 801, the system is synthesized. Synthesis includes generating a logic design of the system to be implemented by the target device. According to an embodiment of the present invention, synthesis generates an optimized logical representation of the system from a hardware description language (HDL) design definition. The HDL design definition includes a description of a universal memory interface that may be used by the system to interface with an external memory system. The universal memory interface includes an external memory interface and a sequencer unit. Synthesis also includes mapping the optimized logic design. Mapping includes determining how to implement logic gates and logic elements in the optimized logic representation with specific resources on the target device. According to an embodiment of the present invention, a netlist is generated from mapping. This netlist may be an optimized technology-mapped netlist generated from the HDL.

At 802, the system is placed. According to an embodiment of the present invention, placement involves placing the mapped logical system design on the target device. Placement works on the technology-mapped netlist to produce a placement for each of the functional blocks. According to an embodiment of the present invention, placement includes fitting the system on the target device by determining which resources on the logic design are to be used for specific logic elements, and other function blocks determined to implement the system as determined during synthesis. Placement may include clustering which involves grouping logic elements together to form the logic clusters present on the target device.

At 803, the placed design is routed. During routing, routing resources on the target device are allocated to provide interconnections between logic gates, logic elements, and other components on the target device.

At 804, an assembly procedure is performed. The assembly procedure involves creating a data file that includes information determined by the compilation procedure described by 801-803.

At 805, the target device is programmed. The data file created may be a bit stream that may be used to program the target device. By programming the target with the data file, components on the target device are physically transformed to implement the system.

At 806, a calibration procedure is identified for the universal memory interface. According to an embodiment of the present invention, the calibration procedure is identified in response to identifying a type of memory system that is to be coupled to or supported by the universal memory interface.

At 807, the sequencer unit is configured with the calibration procedure identified. According to an embodiment of the present invention, the calibration procedure is implemented in code and loaded onto a memory of the sequencer unit. A debugger interface unit may provide an interface to upload the code onto the memory. The sequencer unit executes the calibration procedure by having a processor execute the code in the memory.

Embodiments of the present invention have been described with reference to performing a calibration procedure that center aligns a data signal with a clock that strobes it and expanding a valid window for sampling data. It should be appreciated that other types of calibration procedures may also be performed using the embodiments disclosed. For example, calibration procedures that edge aligns a data signal with a clock that strobes it and other procedures may also be implemented using the sequencer unit and universal memory interface described.

FIGS. 6 and 8 are flow charts that illustrate embodiments of the present invention. Some of the techniques illustrated may be performed sequentially, in parallel or in an order other than that which is described and that the procedures described may be repeated. It should be appreciated that not all of the techniques described are required to be performed, that additional techniques may be added, and that some of the illustrated techniques may be substituted with other techniques.

It should be appreciated that embodiments of the present invention such as the procedures illustrated in FIGS. 6 and 8 may be provided as a computer program product, or software, that may include a computer-readable or machine-readable medium having instructions. The instructions on the computer-readable or machine-readable medium may be used to program a processor, computer system, or other electronic device. The machine-readable medium may include, but is not limited to, a non-transitory medium such as a memory, floppy diskettes, optical disks, CD-ROMs, and magneto-optical disks or other type of media/machine-readable medium suitable for storing electronic instructions. The techniques described herein are not limited to any particular software configuration. They may find applicability in any computing or processing environment. The terms “computer-readable medium” or “machine-readable medium” used herein shall include any medium that is capable of storing or encoding a sequence of instructions for execution by the computer and that cause the computer to perform any one of the methods described herein. Furthermore, it is common in the art to speak of software, in one form or another (e.g., program, procedure, process, application, module, unit, logic, and so on) as taking an action or causing a result. Such expressions are merely a shorthand way of stating that the execution of the software by a processing system causes the processor to perform an action to produce a result.

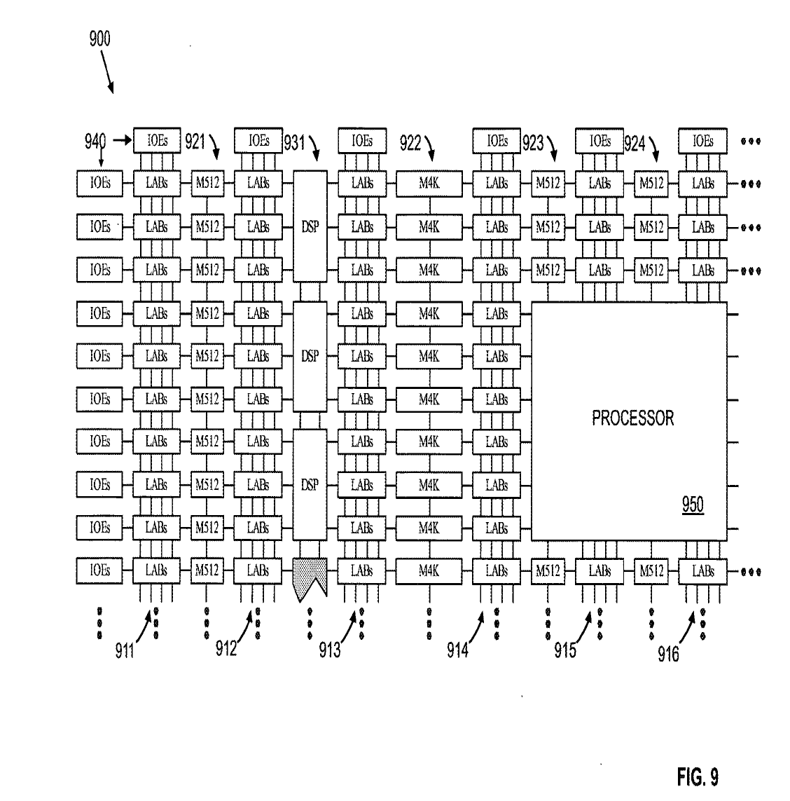

FIG. 9 illustrates a portion of an integrated circuit in which a universal memory interface may be implemented on according to an embodiment of the present invention. The integrated circuit may be, for example, a programmable circuit such as a FPGA that includes a plurality of logic-array blocks (LABs). Each LAB may be formed from a plurality of logic blocks, carry chains, LAB control signals, look up table (LUT) chain, and register chain connection lines. A logic block is a small unit of logic providing efficient implementation of user logic functions. A logic block includes one or more combinational cells, where each combinational cell has a single output, and registers. According to one embodiment of the present invention, the logic block may operate similarly to a logic element (LE), such as those found in the Stratix or Cyclone devices manufactured by Altera® Corporation, or a combinational logic block (CLB) such as those found in Virtex devices manufactured by Xilinx Inc. In this embodiment, the logic block may include a four input LUT with a configurable register. According to an alternate embodiment of the present invention, the logic block may operate similarly to an adaptive logic module (ALM), such as those found in Stratix devices manufactured by Altera Corporation. LABs are grouped into rows and columns across the device 900. Columns of LABs are shown as 911-916. It should be appreciated that the logic block may include additional or alternate components.

The device 900 includes memory blocks. The memory blocks may be, for example, dual port random access memory (RAM) blocks that provide dedicated true dual-port, simple dual-port, or single port memory up to various bits wide at up to various frequencies. The memory blocks may be grouped into columns across the device in between selected LABs or located individually or in pairs within the device 900. Columns of memory blocks are shown as 921-924.

The device 900 includes digital signal processing (DSP) blocks. The DSP blocks may be used to implement multipliers of various configurations with add or subtract features. The DSP blocks include shift registers, multipliers, adders, and accumulators. The DSP blocks may be grouped into columns across the device 900 and are shown as 931.

The device 900 includes an embedded processor 950. The embedded processor is operable to execute program instructions stored in a memory block. In an alternative embodiment of the device 900 where embedded processor 950 is not implemented, it should be appreciated that the programmable resources on the device 900 may be programmed to implement a processor operable to execute program instructions stored in a memory block.

The device 900 includes a plurality of input/output elements (IOES) 940. Each IOE feeds an IO pin (not shown) on the device 900. The IOEs 940 are located at the end of LAB rows and columns around the periphery of the device 900. Each IOE may include a bidirectional IO buffer and a plurality of registers for registering input, output, and output-enable signals.

The device 900 may include routing resources such as LAB local interconnect lines, row interconnect lines (“H-type wires”), and column interconnect lines (“V-type wires”) (not shown) to route signals between components on the target device.

In the foregoing specification, embodiments of the invention have been described with reference to specific exemplary embodiments thereof. It will, however, be evident that various modifications and changes may be made thereto without departing from the broader spirit and scope of the embodiments of the invention. The specification and drawings are, accordingly, to be regarded in an illustrative rather than restrictive sense.

What is claimed is:

1. A universal memory interface on an integrated circuit, comprising:
an external memory interface unit operable to perform data rate conversion for a data signal between a first rate associated with the integrated circuit and a second rate associated with a memory system; and
a sequencer unit operable to calibrate at least one of a delay for the data signal and a delay for a strobe for the data signal by executing a calibration procedure instruction.

2. The apparatus of claim 1, wherein the calibration procedure instruction is executed on an embedded processor on the integrated circuit.

3. The apparatus of claim 1, wherein the calibrated procedure instruction is executed on a processor implemented with programmable circuitry on the integrated circuit.

4. The apparatus of claim 1, wherein the sequencer unit comprises a debug interface unit operable to load the calibration procedure onto a memory accessible to the processor.

5. The apparatus of claim 1, wherein the calibration procedure is loaded in response to identifying a type of the memory system.

6. The apparatus of claim 1, wherein the sequencer unit comprises:
a scan chain manager unit operable to apply a calibrated delay on the data signal and a calibrated delay operable to strobe the data signal; and
a read write manager unit operable to read and write test data to the memory system, wherein the scan chain manager unit and read write manager unit are implemented external to the processor on the integrated circuit.

7. The apparatus of claim 6, wherein the read write manager unit comprises:
a finite state machine operable to transmit commands to access the memory system; and
a global timer operable to track a period of time to transmit the commands based upon a type associated with the memory system.

8. The apparatus of claim 1, wherein the sequencer unit comprises an external memory interface manager unit operable to control first in first outs (FIFOs) in the external memory interface.

9. The apparatus of claim 1, wherein the sequencer unit comprises a phase locked loop (PLL) manager unit operable to adjust a phase of a strobe signal on the integrated circuit.

10. The apparatus of claim 1, wherein the calibration procedure center aligns the data signal with the strobe for the data signal.

11. The apparatus of claim 1, wherein the calibration procedure expands a valid window for sampling the data.

12. The apparatus of claim 1, wherein the calibration procedure comprises:
applying delays on the data signal and the strobe for the data signal while performing one of reading test data from the memory system and writing test data to the memory system;
identifying a range of delays where the data signal is sampled correctly; and
applying a delay on at least one of the data signal and the strobe for the data signal such that the strobe for the data signal samples the data signal at a center of the range of delays where the data signal is sampled correctly.

13. The apparatus of claim 1, wherein the sequencer unit is operable to perform calibration during initialization of the system and also during runtime in response to a request from a memory controller.

14. A universal memory interface on an integrated circuit, comprising:
an external memory interface unit operable to perform data rate conversion for a data signal between a first rate associated with the integrated circuit and a second rate associated with a memory system; and
a sequencer unit comprising a finite state machine, a scan chain manager, and a read write manager, wherein the finite state machine is operable to center align the data signal with a strobe signal for the data signal by performing a calibration procedure, wherein the scan chain manager is operable to apply a delay on the data signal and a delay on the strobe for the data signal in response to the calibration procedure, and wherein the read write manager unit is operable to read test data from and write test data to the memory system in response to the calibration procedure, wherein the scan chain manager unit and read write manager unit are implemented external to the finite state machine.

15. The apparatus of claim 14, wherein the calibration procedure comprises:
applying delays on the data signal and the strobe for the data signal while performing one of reading test data from the memory system and writing test data to the memory system;
identifying a range of delays where the data signal is sampled correctly; and
applying a delay on at least one of the data signal and the strobe for the data signal such that the strobe for the data signal samples the data signal at a center of the range of delays where the data signal is sampled correctly.

16. A method for configuring a universal memory interface, comprising:
identifying a calibration procedure to perform on the universal memory interface; and
loading calibration procedure instructions associated with the calibration procedure onto a memory in the sequencer unit of the universal memory interface.

17. The method of claim 18, wherein the calibration procedure center aligns a data signal transmitted between the universal memory interface and a memory system with a strobe for the data signal.

18. The method of claim 16, wherein the calibration procedure expands a valid window for sampling data transmitted between the universal memory interface and a memory system.

19. The method of claim 16, wherein identifying the calibration procedure comprises identifying a type of a memory system coupled to the universal memory interface.

20. The method of claim 16, wherein the calibration procedure comprises:
applying delays on the data signal and the strobe for the data signal while performing one of reading test data from the memory system and writing test data to the memory system;
identifying a range of delays where the data signal is sampled correctly; and
applying a delay on at least one of the data signal and the strobe for the data signal such that the strobe for the data signal samples the data signal at a center of the range of delays where the data signal is sampled correctly.
